(19) United States
(12) Patent Application Publication
(10) Pub. No.: US 2013/0015553 A1
(43) Pub. Date: Jan. 17, 2013

(54) High Voltage Isolation Trench, Its Fabrication Method and MOS Device

(71) Applicant: Yanfeng Jiang, Beijing (CN)

(72) Inventor: Yanfeng Jiang, Beijing (CN)

(73) Assignee: NORTH CHINA UNIVERSITY OF TECHNOLOGY, Beijing (CN)

(21) Appl. No.: 13/349,675

(22) Filed: Jan. 13, 2012

(30) Foreign Application Priority Data
Jan. 14, 2011 (CN) 201110008489.3

(51) Int. Cl. H01L 23/48; H01L 21/768

(52) U.S. Cl. 257/508; 438/430; 257/E23.011; 257/E21.586

(57) ABSTRACT

A type of high voltage isolation trench, its fabrication method and an MOS device are disclosed. The isolation trench includes a trench extending to a buried oxide layer of a wafer, with high concentration N⁺ injected to a side wall of the trench, polysilicon being filled in the trench and oxides are being filled between the side wall of the trench and the polysilicon. Multiple composite structures are used to fill the vacant trench to reduce stress brought by trenching so as to improve performance of the device on one hand and to achieve the purpose of increasing breakdown voltage and improving superficial flatness on the other hand.

### CROSS-REFERENCE TO RELATED APPLICATIONS

This application claims priority to Chinese Patent Application No. 201110008489.3, filed on Jan. 14, 2011, the disclosure of which is herein incorporated herein by reference.

### FIELD OF THE INVENTION

The field is directed to types of isolation trench technology in a semiconductor integrated circuit.

### BACKGROUND OF THE INVENTION

In a semiconductor integrated circuit, silicon is conductive and must be electrically isolated from other elements in the circuit to avoid electric connection with each other. Electric isolation between high voltage transistors and low voltage transistors is especially important. If no isolation is provided between high voltage transistors and low voltage transistors, then minor ineffective current will be generated, resulting in power consumption increase, on one hand, and a high voltage, which cannot reliably be borne by low voltage devices with comparative thin gate oxide layer, and which is bridged between the low voltage device and substrate on the other hand. Therefore, isolation must be provided between the high voltage transistors and the low voltage transistors. The relatively common isolation techniques are PN junction isolation, self isolation, medium isolation, etc., all of which have advantages and disadvantages.

PN junction isolation is known to fabricate active device on an N⁻ epitaxial layer on a P⁻ substrate and penetrate a P⁺ deep diffusion of the epitaxial layer to provide isolation between the elements or devices. A high concentration N+ buried layer results in reduction of serial resistance. In the conventional PN junction isolation, RESURF high voltage device can also be adopted to expand the voltage range. In a HVIC (high voltage integrated circuit) using PN junction isolation, bipolar transistors and MOS tube can both be incorporated for the reason that devices in the PN junction isolation regions are basically independent of each other. Therefore, for a MOS device, the constraint that a high voltage MOS device in self isolation must use a common-source structure is eliminated.

There are at least the following defects existing in the foregoing conventionally known processes. In principle, PN junction isolation is applicable to various processes and its application scope is wide. However, as isolation junction occupies a large area in an HVIC, causing a low degree of integration, there are parasitic capacitance and PNPN parasitic effects. Both PN junction isolation and self isolation have the defect of leakage current increase during high temperature. Though such leakage current increase is allowable for most power applications, it leads to reduction of degree of insulation between elements on the same chip, resulting in cross linking between devices and voltage lockout under certain conditions.

There remains a need for improved types of high voltage isolation trenches, fabrication methods and MOS devices.

### SUMMARY OF THE INVENTION

In one preferred embodiment, a high voltage isolation trench comprises a trench extending to a buried oxide layer of a wafer, with a high concentration N⁺ injected to a side wall of the trench, polysilicon filled in the trench and oxides filled between the side wall of the trench and the polysilicon.

In one preferred embodiment, a method of fabricating the foregoing high voltage isolation trench of, comprises the steps of:

a) generating a mask film layer on the wafer to define the trench to be etched;

b) etching unmasked areas of the wafer to at least a proximate surface of the buried oxide layer; and

c) filling the etched trench, by first injecting high concentration N⁺ to the side wall of the vacant trench, filling the trench with polysilicon, and filling oxides between the side wall of the vacant trench and the polysilicon.

The high voltage isolation trench as disclosed can also be used for the MOS device of the invention.

### BRIEF DESCRIPTION OF THE DRAWINGS

Further features and advantages of the invention will become apparent when the following detailed description is read in view of the drawing figures, in which like reference numerals refer to like parts:

FIG. 1 shows a cross-section of an integrated circuit incorporating an exemplary high voltage isolation trench;

FIG. 2 shows a cross-section of an integrated circuit showing schematic equivalent electrical circuit of the integrated circuit of FIG. 1, but shown on a different scale of size

### DETAILED DESCRIPTION OF THE INVENTION

The examples and drawings provided in the detailed description are merely examples, which should not be used to limit the scope of the claims in any claim construction or interpretation.

The following terms used throughout the specification are abbreviations. “MOS” stands for “metal-oxide-semiconductor.” “VDMOS” stands for “vertical diffused metal-oxide-semiconductor.”

One object of the invention, among many, is to provide to a type of high voltage isolation trench, its fabrication method and an MOS device to reduce stress caused by trenching so as to improve performance of the device, on one hand, and achieve the purpose of increasing breakdown voltage and improving superficial flatness, on the other hand.

One preferred embodiment of the high voltage isolation trench comprises a trench extending to a buried oxide layer of wafer, with high concentration N+ injected into side wall of the trench, polysilicon filled in the trench and oxides filled between the side wall of the trench and the polysilicon.

For a preferred embodiment of the fabrication method of the high voltage isolation trench, the following steps are included.

First, one mask film layer is generated on the wafer to define the trench to be etched and the trench is etched to the buried oxide layer of the wafer.

Then the etched trench is filled, including such substances in detail: First, high concentration N+ is injected to the side wall of the vacant trench. Then, polysilicon is filled in the vacant trench and oxides are filled between the side wall of the vacant trench and the polysilicon.

In one example, the process of etching the trench can be divided into several steps:

After the first step of etching is finished, polymers are filled to the etched trench. Then during the next step of etching, polymers at the bottom are etched away, while polymers on the side wall are retained. The step will be repeated until the required depth is acquired.

For an exemplary MOS device, the detailed preferred embodiment is that isolation trench of the MOS device uses the high voltage isolation trench.

The MOS device can comprise a power VDMOS device which can bear a voltage of 1000 V.

Multiple composite structures are adopted to fill the vacant trench to reduce stress brought by trenching so as to improve performance of the device, on one hand, and achieve the purpose of increasing breakdown voltage and improving superficial flatness, on the other hand.

The exemplary high voltage isolation technology as disclosed herein substitutes for the conventional PN junction isolation process and provides better isolation between devices, leading to substantial reduction of mutual interruption between circuits or devices.

The exemplary isolated MOS device as disclosed herein is capable of bearing a voltage up to 1000 V, meeting requirements of isolation between high voltage and low voltage in the high voltage integrated circuit. After trenching, N+ injections, oxides and polysilicon are filled in the vacant trench, respectively. The isolation process substitutes for the conventional PN junction isolation process and provides better isolation between devices, leading to substantial reduction of mutual interruption between circuits or devices.

### Exemplary Process

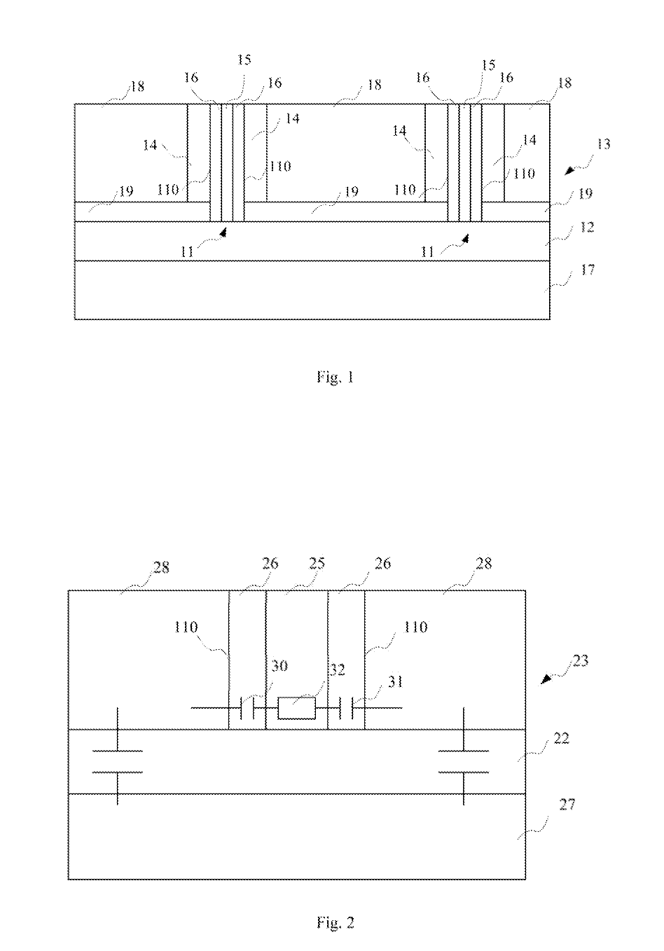

As illustrated in FIG. 1, a high voltage isolation trench comprises a trench 11 extending to a buried oxide layer 12 of a wafer 13, with a high concentration N+ 14 injections into a side wall 110 of the trench 11, polysilicon 15 filled in the trench 11 and oxides 16 filled between the side wall 110 of the trench 11 and the polysilicon 15. As illustrated in FIG. 1, the wafer 13 has a substrate 17, device region 18, and epitaxy layer 19.

An exemplary method of fabrication occurs as follows: The first step is “making hole”: First, one mask film layer is generated on the wafer to determine where etching is required. During etching downwards, after the first time of etching is completed, polymers are filled to the etched “pit”. Then during the next step of etching, polymers at the bottom are etched away, while polymers on the side wall are retained to avoid transverse etching. The step will be repeated until the required depth is acquired.

The second step is to fill the resulting, chamfered trench. Side wall of the vacant trench is injected with high concentration N+ to provide a low-resistance junction between the side wall and the buried oxide layer. Then, polysilicon is filled in the vacant trench and oxides are filled between the vacant trench and the polysilicon.

After the trenching is completed, one layer of oxides is used for cover above. During trench making, the chamfered trench extends downwards into the buried oxide layer and trenching cannot be stopped when it is only conducted into the silicon. Therefore, “over-etching” will be conducted, but the over-etching brings another problem: in case of over-etching, ions will diffuse on the side wall of the vacant trench to form a coarse surface which will reduce the isolation capacity of the trench after the trench is filled. Therefore, during trench making, it is ensured that etching is conducted to the buried oxide layer and meanwhile excessive etching should be avoided.

In one example, the invention can be applied to fabricate power VDMOS which can bear a voltage up to 1000 V. As the trenching isolation technique is adopted, the multiple-trench process can be adopted to improve voltage bearability of devices so as to enable the devices to supersedes the limits of voltage bearability of 1000 V as permitted by domain area.

As illustrated in FIG. 2, an exemplary isolation structure comprises oxides 26 and N+ injections between the side wall 110, comparable to N+ injections 14 in FIG. 1, and the polysilicon 25. As illustrated in FIG. 2, the wafer 23 has a buried oxide layer 22, a substrate 27 and device region 28. Therefore, an exemplary isolation trench can be taken as the series connection for the two capacitors 30 and 31 and the series resistance 32. The isolation trench structure consists of oxides, polysilicon fillings and oxides. The thickness of the oxides and polysilicon in the isolation trench structure is determined by specific processes. The advantage of the structure lies in that multiple composite structures are adopted to fill the vacant trench to reduce stress brought by trenching so as to improve performance of the device, on one hand, and achieve the purpose of increasing breakdown voltage and improving superficial flatness, on the other hand.

It can be seen from the technical scheme provided in the invention that as high concentration N+ is injected to the side wall of the trench, polysilicon is filled in the trench and oxides are filled between the side wall of the trench and the polysilicon. The high voltage isolation trench, its fabrication method and an MOS device as provided in the embodiments of the invention adopt multiple composite structures to fill the vacant trench to reduce stress brought by trenching so as to improve performance of the device, on one hand, and achieve the purpose of increasing breakdown voltage and improving superficial flatness, on the other hand.

The following is a list of reference numerals and associated parts as used in this specification and drawings:

| Reference Numeral | Part |
|---|---|
| 11 | Trench |
| 12 | Buried oxide Layer |
| 13 | Wafer |
| 14 | N+ injections |
| 15 | Polysilicon |
| 16 | Oxides |
| 17 | Substrate |
| 18 | Device Region |
| 19 | Epitaxy layer |
| 22 | Buried oxide layer |
| 23 | Wafer |
| 25 | Polysilicon |
| 26 | Oxides |
| 27 | Substrate |
| 28 | Device region |
| 30 | Capacitor |
| 31 | Capacitor |
| 32 | Resistance |
| 110 | Side wall |

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A high voltage isolation trench comprising a trench extending to a buried oxide layer of a wafer of an integrated circuit, wherein high concentration N⁺ is injected to a side wall of the trench, polysilicon is filled in the trench and oxides are filled between the side wall of the trench and the polysilicon.

2. A method of fabricating the high voltage isolation trench of claim 1, comprising the steps of:
a) generating a mask film layer on the wafer to define the trench to be etched in unmasked areas of the wafer;
b) etching unmasked areas of the wafer to a depth that reaches at least a proximate surface of the buried oxide layer; and
c) filling the etched trench, by first injecting high concentration N⁺ to the side wall of the vacant trench, and filling the trench with polysilicon and filling oxides between the side wall of the vacant trench and the polysilicon.

3. The method of claim 2, wherein the step of etching the unmasked areas of the wafer includes the sub-steps of:
a) after a first sub-step of etching is finished, filling the etched trench with polymers, and
b) in a next sub-step of etching, etching away the polymers at the bottom of the trench while retaining the polymers on the side wall of the trench, and repeating this step (b) until a required depth is attained.

4. A MOS device comprising a MOS device having an isolation trench using the high voltage isolation trench of claim 1.

5. A MOS device of claim 4, wherein the MOS device comprises a power VDMOS device which can bear a voltage of 1000 V.

6. A MOS device comprising a MOS device having an isolation trench using the high voltage isolation trench produced by the method of claim 2.

7. A MOS device of claim 6, wherein the MOS device comprises a power VDMOS device which can bear a voltage of 1000 V.
